(19) United States
(12) Patent Application Publication
(10) Pub. No.: US 2026/0162758 A1
(43) Pub. Date: Jun. 11, 2026

(54) BROADCAST CIRCUIT FOR FUSE ARRAY, BROADCAST METHOD FOR FUSE ARRAY, AND MEMORY APPARATUS

(71) Applicant: CXMT Corporation, Hefei (CN)

(72) Inventor: Wei Zhang, Hefei (CN)

(73) Assignee: CXMT Corporation, Hefei (CN)

(21) Appl. No.: 19/181,827

(22) Filed: Apr. 17, 2025

Related U.S. Application Data
(63) Continuation of application No. PCT/CN2024/095711, filed on May 28, 2024.

(30) Foreign Application Priority Data
Dec. 25, 2023 (CN) 202311804385.2

(51) Int. Cl. G11C 29/00; G11C 8/04; G11C 8/18

(52) U.S. Cl. CPC G11C 29/789; G11C 8/04; G11C 8/18

(57) ABSTRACT

Provided a broadcast circuit for a fuse array, a broadcast method for a fuse array, and a memory apparatus. The broadcast circuit for the fuse array includes: a broadcast address detector, configured to receive a broadcast fuse address count to generate N enable signals; and N sub-broadcast circuits, each includes: a gating circuit, connected to the fuse array and the broadcast address detector, and configured to: receive one of the enable signals, a broadcast clock signal, and broadcast data, and output a gated broadcast clock signal and gated broadcast data when the enable signal is valid; and a broadcast bus and a latch circuit, where the broadcast bus is connected to the gating circuit and the latch circuit, and the broadcast bus is configured to transmit the gated broadcast clock signal and the gated broadcast data to the latch circuit.

This application is a continuation of International Patent Application No. PCT/CN2024/095711, filed on May 28, 2024, which is based on and claims priority of the Chinese Patent Application No. 202311804385.2, filed with the China National Intellectual Property Administration on Dec. 25, 2023 and entitled “BROADCAST CIRCUIT FOR FUSE ARRAY AND BROADCAST METHOD FOR FUSE ARRAY”. The above-referenced application is incorporated herein by reference in their entireties.

### BACKGROUND

A memory apparatus may include a memory array and a fuse array. The fuse array may store repair information related to the memory array or other operation information. After the memory apparatus is powered on, fuse broadcast needs to be performed to transmit, through a broadcast circuit, data stored in the fuse array to local registers in the memory apparatus. However, because disposing locations of the local registers in the memory apparatus are relatively scattered, a case of a mismatch between broadcast data and a broadcast clock signal is prone to occur in a fuse broadcast process, which causes an error in data ultimately transmitted to the local registers. Therefore, how to improve reliability of fuse broadcast becomes an urgent problem to be resolved at present.

### SUMMARY

The disclosure relates to the technical field of memories, and in particular to a broadcast circuit for a fuse array, a broadcast method for a fuse array, and a memory apparatus, to resolve at least one problem in the conventional technology.

To achieve the foregoing objective, the technical solutions in the embodiments of the present disclosure are implemented as follows:

According to a first aspect, an embodiment of the present disclosure provides a broadcast circuit for a fuse array, including:
a broadcast address detector, configured to receive a broadcast fuse address count to generate N enable signals, where N is a positive integer greater than 1; and
N sub-broadcast circuits, where each of the sub-broadcast circuits includes:
a gating circuit, connected to the fuse array and the broadcast address detector, and configured to: receive one of the enable signals, a broadcast clock signal, and broadcast data, and output a gated broadcast clock signal and gated broadcast data when the enable signal is valid; and
a broadcast bus and a latch circuit, where the broadcast bus is connected to the gating circuit and the latch circuit, and the broadcast bus is configured to transmit the gated broadcast clock signal and the gated broadcast data to the latch circuit.

According to a second aspect, an embodiment of the present disclosure provides a broadcast method for a fuse array, including the steps as follows:
a broadcast address detector receives a broadcast fuse address count to generate N enable signals, where N is a positive integer greater than 1;
a gating circuit in one of N sub-broadcast circuits receives one of the enable signals, a broadcast clock signal, and broadcast data, and outputs a gated broadcast clock signal and gated broadcast data when the enable signal is valid;
a broadcast bus in the sub-broadcast circuit transmits the gated broadcast clock signal and the gated broadcast data to a latch circuit.

According to a third aspect, an embodiment of the present disclosure provides a memory apparatus, including a memory array, a fuse array, and the broadcast circuit according to any one of the implementations of the first aspect. The memory array is configured to store data, the fuse array is configured to store repair information related to the memory array, and the broadcast circuit is configured to broadcast the fuse array after the memory apparatus is powered on, to transmit, through the broadcast circuit, the repair information stored in the fuse array to local registers in the memory apparatus.

### BRIEF DESCRIPTION OF DRAWINGS

FIG. 1 is a schematic diagram of a broadcast circuit for a fuse array according to an embodiment of the present disclosure;

FIG. 2 is a schematic diagram of composition of a gating circuit according to an embodiment of the present disclosure;

FIG. 3 is a circuit diagram of a gating circuit according to an embodiment of the present disclosure;

FIG. 4 is a circuit diagram of a latch circuit according to an embodiment of the present disclosure;

FIG. 5 is a first schematic arrangement diagram of a broadcast circuit for a fuse array according to an embodiment of the present disclosure;

FIG. 6 is a second schematic arrangement diagram of a broadcast circuit for a fuse array according to an embodiment of the present disclosure;

FIG. 7 is a schematic flowchart of a broadcast method for a fuse array according to an embodiment of the present disclosure; and

FIG. 8 is a schematic diagram of composition of a memory apparatus according to an embodiment of the present disclosure.

### DESCRIPTION OF EMBODIMENTS

Example implementations disclosed by the present disclosure are described in more detail below with reference to the accompanying drawings. Although the example implementations of the present disclosure are shown in the accompanying drawings, it should be understood that the present disclosure may be implemented in various forms without being limited by the specific implementations described herein. Instead, these implementations are provided to implement a more thorough understanding of the present disclosure and to fully convey the scope disclosed by the present disclosure to a person skilled in the art.

In the following descriptions, a large quantity of specific details are given to provide a more thorough understanding of the present disclosure. However, it is clear to a person skilled in the art that the present disclosure may be implemented without one or more of these details. In other examples, some technical features well-known in the art are not described to avoid confusion with the present disclosure. That is, not all features of actual embodiments are described herein, and well-known functions and structures are not described in detail.

In the accompanying drawings, the same reference numerals represent the same elements throughout.

It should be understood that spatial relationship terms “under”, “below”, “underlying”, “beneath”, “over”, “above”, and the like may be utilized herein for convenience of description, to describe the relationship between one element or feature and another element or feature shown in the figures. It should be understood that in addition to the orientations shown in the figures, the spatial relationship terms are further intended to include different orientations of components in use and operation. For example, if the component in the accompanying drawings is flipped, an element or a feature described as “below another element” is oriented to be “above” the another element or feature. Therefore, the example terms “below” and “beneath” may include orientations of being above and being below. The component may be otherwise oriented (rotated by 90 degrees or oriented in another manner), and the spatial descriptors utilized herein are interpreted accordingly.

The terms utilized herein are intended merely to describe specific embodiments and are not construed as a limitation on the present disclosure. As utilized herein, the singular forms “a/an”, “one”, and “the” are also intended to include plural forms unless otherwise clearly indicated in the context. It should be further understood that the terms “constitute” and/or “include” are utilized in the specification to determine the presence of the features, integers, steps, operations, elements, and/or components, but not rule out the presence or addition of one or more other features, integers, steps, operations, elements, components, and/or groups. As utilized herein, the term “and/or” includes any and all combinations of the related items listed.

A memory apparatus may include a memory array and a fuse array. The memory array is configured to store user data, and the fuse array is configured to store repair information related to the memory array, e.g., row repair information and column repair information, and other operation information. After the memory apparatus is powered on, fuse broadcast needs to be performed to transmit, through a broadcast circuit, data stored in the fuse array to local registers in the memory apparatus, so that the memory apparatus reads the data stored in the fuse array when performing an operation such as reading/writing. However, disposing locations of the local registers in the memory apparatus are relatively scattered, and a broadcast bus needs to pass through all the local registers. As a result, winding of the broadcast bus is relatively long, and a case of a mismatch between broadcast data and a broadcast clock signal is prone to occur in a fuse broadcast process, which causes an error in data ultimately transmitted to the local registers. Consequently, reliability of fuse broadcast is reduced.

Therefore, how to improve reliability of fuse broadcast becomes an urgent problem to be resolved at present. Therefore, the following implementations are provided in the present disclosure.

The present disclosure provides a broadcast circuit for a fuse array, including: a broadcast address detector, configured to receive a broadcast fuse address count to generate N enable signals, where N is a positive integer greater than 1; and N sub-broadcast circuits, where each of the sub-broadcast circuits includes: a gating circuit, connected to the fuse array and the broadcast address detector, and configured to: receive one of the enable signals, a broadcast clock signal, and broadcast data, and output a gated broadcast clock signal and gated broadcast data when the enable signal is valid; and a broadcast bus and a latch circuit, where the broadcast bus is connected to the gating circuit and the latch circuit, and the broadcast bus is configured to transmit the gated broadcast clock signal and the gated broadcast data to the latch circuit.

In the embodiments of the present disclosure, the broadcast circuit for the fuse array includes N sub-broadcast circuits, and data stored in the fuse array may be separately broadcast through the N sub-broadcast circuits. The broadcast circuit for the fuse array provided in the present disclosure is described in detail below with an example in which N is equal to 2.

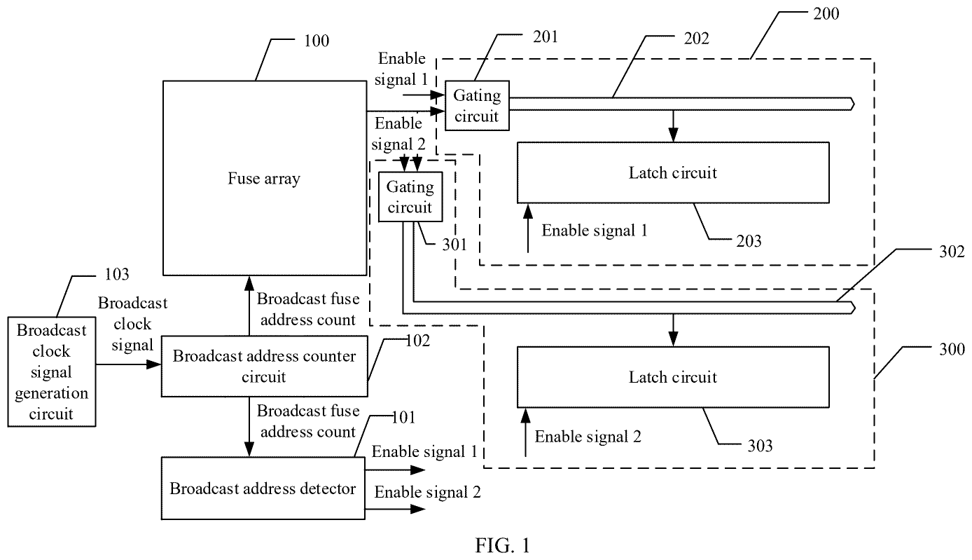

FIG. 1 is a schematic diagram of a broadcast circuit for a fuse array according to an embodiment of the present disclosure. As shown in FIG. 1, the broadcast circuit for the fuse array includes a broadcast address detector 101 and two sub-broadcast circuits, and each of the sub-broadcast circuits includes a gating circuit, a broadcast bus, and a latch circuit. A first sub-broadcast circuit 200 includes a gating circuit 201, a broadcast bus 202, and a latch circuit 203, and a second sub-broadcast circuit 300 includes a gating circuit 301, a broadcast bus 302, and a latch circuit 303.

In some embodiments, the broadcast circuit for the fuse array further includes a broadcast address counter circuit 102 and a broadcast clock signal generation circuit 103. The broadcast circuit for the fuse array may be enabled in response to a fuse broadcast command, the broadcast clock signal generation circuit 103 may generate a broadcast clock signal, and the broadcast address counter circuit 102 may receive the broadcast clock signal, and generate a broadcast fuse address count based on the broadcast clock signal.

In some specific examples, the fuse array 100 may include multiple areas, and each of the areas includes fuse memory cells arranged in multiple arrays. The broadcast address counter circuit 102 may sequentially send multiple groups of broadcast fuse address counts to the fuse array 100 and the broadcast address detector 101. One group of broadcast fuse address counts may include an area count, a row address count, and a column address count, and corresponds to one fuse memory cell in the fuse array 100. The fuse array 100 may output, after receiving the broadcast fuse address counts, data stored in the fuse memory cell corresponding to the broadcast fuse address counts. The data output by the fuse array 100 is broadcast data.

In some embodiments, the broadcast address detector 101 is specifically configured to: receive a broadcast fuse address count to generate a quantity of broadcast fuses, and compare the quantity of broadcast fuses with a preset quantity in a preset list to generate N enable signals.

In this embodiment of the present disclosure, a broadcast progress of the fuse array may be controlled through the broadcast address detector 101. The broadcast address detector 101 may include a preset list, and the preset list includes N preset quantities. For example, N is 2. A quantity of fuses that may be broadcast by the first sub-broadcast circuit 200 is X, and a quantity of fuses that may be broadcast by the second sub-broadcast circuit 300 is Y. In this case, the preset list may include two preset quantities, where a first preset quantity may be X, and a second preset quantity may be X+Y. The broadcast address detector 101 may receive a broadcast fuse address count to generate a quantity of broadcast fuses, and compare the quantity of broadcast fuses with the first preset quantity and the second preset quantity. The broadcast address detector 101 may generate an enable signal 1 and an enable signal 2 based on a result of the comparison between the quantity of broadcast fuses and the preset quantities. The first sub-broadcast circuit 200 may receive the enable signal 1, and the second sub-broadcast circuit 300 may receive the enable signal 2. Specifically, when the quantity of broadcast fuses is less than X, the enable signal 1 is valid, the enable signal 2 is invalid, and the broadcast data may be broadcast through the first sub-broadcast circuit 200. When the quantity of broadcast fuses is greater than or equal to X and is less than X+Y, the enable signal 1 is invalid, the enable signal 2 is valid, and the broadcast data may be broadcast through the second sub-broadcast circuit 300. When the quantity of broadcast fuses is equal to X+Y, both the enable signal 1 and the enable signal 2 are invalid, and broadcast of the fuse array is completed.

It should be noted that, in this embodiment of the present disclosure, a signal being valid means that the signal is at a first logic level, and a signal being invalid means that the signal is at a second logic level. The first logic level may be a higher level relative to the second logic level, and the second logic level may be a lower level relative to the first logic level.

In some embodiments, the broadcast clock signal generated by the broadcast clock signal generation circuit 103 may be further utilized as a clock signal for outputting the broadcast data by the fuse array 100. The broadcast clock signal may be output in synchronization with the broadcast data, and may be transmitted to the latch circuit through the gating circuit and the broadcast bus in the sub-broadcast circuit.

In this embodiment of the present disclosure, gating circuits in N sub-broadcast circuits may have the same circuit structure. Composition and a circuit structure of a gating circuit are described below by taking the gating circuit 201 in the first sub-broadcast circuit 200 as an example.

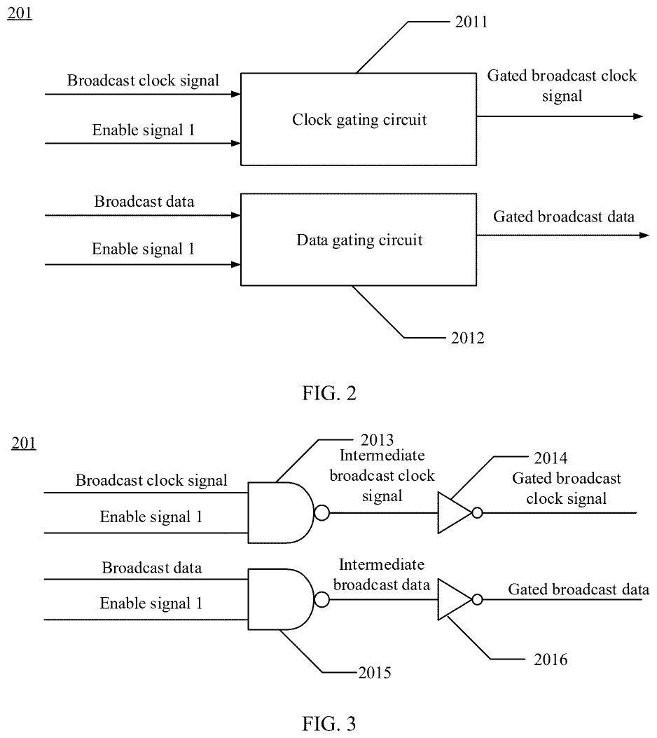

In some embodiments, FIG. 2 is a schematic diagram of composition of a gating circuit according to an embodiment of the present disclosure. As shown in FIG. 2, the gating circuit 201 includes: a clock gating circuit 2011, configured to perform a logical operation on the enable signal 1 and the broadcast clock signal to generate a gated broadcast clock signal; and a data gating circuit 2012, configured to perform the logical operation on the enable signal 1 and the broadcast data to generate gated broadcast data.

In a specific example, FIG. 3 is a circuit diagram of a gating circuit according to an embodiment of the present disclosure. With reference to FIG. 1, FIG. 2, and FIG. 3, the clock gating circuit 2011 and the data gating circuit 2012 each include a NAND gate and a NOT gate, and an output terminal of the NAND gate is connected to an input terminal of the NOT gate. The NAND gate 2013 of the clock gating circuit 2011 is configured to: receive the enable signal 1 and the broadcast clock signal, and output an intermediate broadcast clock signal. The NOT gate 2014 of the clock gating circuit 2011 is configured to: receive the intermediate broadcast clock signal, and output the gated broadcast clock signal. The NAND gate 2015 of the data gating circuit 2012 is configured to: receive the enable signal 1 and the broadcast data, and output intermediate broadcast data. The NOT gate 2016 of the data gating circuit 2012 is configured to: receive the intermediate broadcast data, and output the gated broadcast data.

In this embodiment of the present disclosure, a gating circuit in one sub-broadcast circuit receives one enable signal, and the N enable signals generated by the broadcast address detector are correspondingly output to N sub-broadcast circuits. The gating circuit outputs the gated broadcast clock signal and the gated broadcast data only when the enable signal received by the gating circuit is valid. A maximum of one of the N enable signals is valid, so that data stored in the fuse array can be separately broadcast through different sub-broadcast circuits.

In some embodiments, the broadcast bus may include a data bus and a clock bus, the data bus may be configured to transmit the gated broadcast data to the latch circuit, and the clock bus may be configured to transmit the gated broadcast clock signal to the latch circuit.

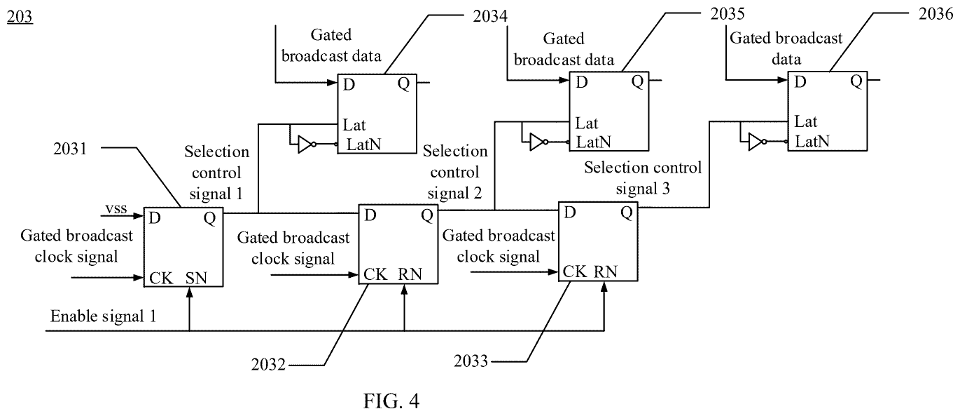

In some embodiments, FIG. 4 is a circuit diagram of a latch circuit according to an embodiment of the present disclosure. With reference to FIG. 1 and FIG. 4, the latch circuit 203 in the first sub-broadcast circuit 200 is taken as an example to describe a latch circuit in the broadcast circuit provided in the present disclosure.

In some embodiments, as shown in FIG. 4, the latch circuit 203 includes M flip-flops and M latches, and a control terminal of each of the latches is connected to an output terminal of one of the flip-flops. M is a positive integer greater than 1. Herein, for example, M is equal to 3. The latch circuit 203 includes three flip-flops and three latches. An output terminal Q of a first flip-flop 2031 is connected to a control terminal Lat of a first latch 2034, and is connected to an inverted control terminal LatN of the first latch 2034 through an inverter. An output terminal Q of a second flip-flop 2032 is connected to a control terminal Lat of a second latch 2035, and is connected to an inverted control terminal LatN of the second latch 2035 through an inverter. An output terminal Q of a third flip-flop 2033 is connected to a control terminal Lat of a third latch 2036, and is connected to an inverted control terminal LatN of the third latch 2036 through an inverter.

In this embodiment of the present disclosure, the M flip-flops in the latch circuit are configured to: receive the gated broadcast clock signal and one enable signal, and output M selection control signals when the enable signal is valid, where a maximum of one of the M selection control signals is valid. The latches are configured to: receive the selection control signals and the gated broadcast data, and latch and output the gated broadcast data when the selection control signals are valid.

In some specific examples, still referring to FIG. 4, the three flip-flops in the latch circuit 203 are configured to: receive the gated broadcast clock signal and the enable signal 1, and output three selection control signals when the enable signal 1 is valid. The three flip-flops are connected in series. The first flip-flop 2031 includes: a first data input terminal D, configured to receive a ground voltage VSS; a first clock input terminal CK, configured to receive the gated broadcast clock signal; and a setting terminal SN, configured to receive the enable signal 1. A flip-flop other than the first flip-flop 2031 in the three flip-flops includes: a second data input terminal D connected to an output terminal Q of a previous flip-flop, where for example, a data input terminal D of the second flip-flop 2032 is connected to the output terminal Q of the first flip-flop 2031, and a data input terminal D of the third flip-flop 2033 is connected to the output terminal Q of the second flip-flop 2032; a second clock input terminal CK, configured to receive the gated broadcast clock signal; and a reset terminal RN, configured to receive the enable signal 1.

In this embodiment of the present disclosure, when the enable signal 1 is valid, the first flip-flop 2031 may generate a selection control signal 1, the second flip-flop 2032 may generate a selection control signal 2, and the third flip-flop 2033 may generate a selection control signal 3. At the same moment, a maximum of one selection control signal is valid, that is, at the same moment, a maximum of one latch is enabled. A data input terminal D of the enabled latch receives and latches the gated broadcast data, and outputs 1-bit gated broadcast data through an output terminal Q.

In some specific examples, the latch circuit 303 in the second sub-broadcast circuit 300 may have a circuit structure similar to that of the latch circuit 203 in the first sub-broadcast circuit 200.

It should be noted that, in the foregoing embodiment, M being equal to 3 is taken as an example, but the present disclosure is not limited thereto. In some other embodiments, M may be any positive integer greater than 1, such as 4, 7, 16, or 32.

In this embodiment of the present disclosure, the broadcast address detector may generate N enable signals, each of the N sub-broadcast circuits may receive one enable signal, the gating circuit in the sub-broadcast circuit may output gated broadcast data and a gated broadcast clock signal when the enable signal is valid, the broadcast bus in the sub-broadcast circuit may transmit the gated broadcast data and the gated broadcast clock signal to the latch circuit, and the latch circuit may latch and output the gated broadcast data when the enable signal is valid. A maximum of one of the N enable signals is valid, so that broadcast of the fuse array can be separately completed through the N sub-broadcast circuits. The length of broadcast buses in the N sub-broadcast circuits is less than the length of a single broadcast bus that needs to pass through all local registers. In other words, according to the broadcast circuit for the fuse array provided in the present disclosure, the winding length of a broadcast bus can be shortened, and the risk of a mismatch between broadcast data and a broadcast clock signal in a process of broadcasting the fuse array can be reduced, thereby improving reliability of fuse array broadcast.

In some embodiments, multiple latches and multiple flip-flops in the latch circuit may form local registers, e.g., a local register of a row decoder, a local register of a column decoder, and a test mode register. The local register of the row decoder may store row repair information in the fuse array, the local register of the column decoder may store column repair information in the fuse array, and the test mode register may store related parameter information in the fuse array for testing a memory apparatus.

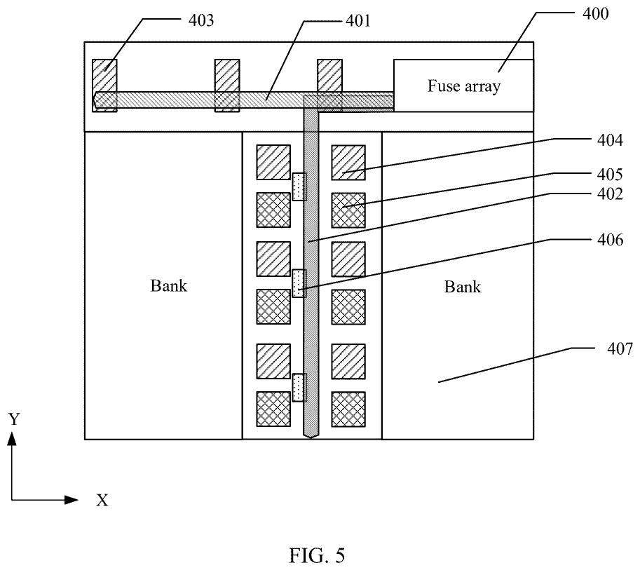

In some specific examples, FIG. 5 is a schematic arrangement diagram of a broadcast circuit for a fuse array according to an embodiment of the present disclosure. For ease of observation, a broadcast bus 401 in a first sub-broadcast circuit and a broadcast bus 402 in a second sub-broadcast circuit are shown in a perspective effect. As shown in FIG. 5, a fuse array 400 is located in a peripheral circuit on a side of a bank 407 in a Y direction, and a broadcast circuit for the fuse array includes two sub-broadcast circuits connected to the fuse array 400. The broadcast bus 401 in the first sub-broadcast circuit extends in an X direction, and is connected to multiple test mode registers 403 that are located on one side of the fuse array 400 and that are arranged in the X direction. The broadcast bus 402 in the second sub-broadcast circuit includes a part extending in the X direction and a part extending in the Y direction, and is connected to multiple registers located between two banks 407. The multiple registers may include local registers 404 of multiple column decoders, local registers 405 of multiple row decoders, and multiple test mode registers 406. In this example, compared with a single broadcast bus that needs to be connected to multiple test mode registers 403 located on one side of the fuse array 400 and multiple registers located between two banks 407, the broadcast bus 401 in the first sub-broadcast circuit and the broadcast bus 402 in the second sub-broadcast circuit have a smaller length. At the same moment, one of the broadcast bus 401 in the first sub-broadcast circuit and the broadcast bus 402 in the second sub-broadcast circuit is enabled, so that the winding length of a broadcast bus for transmitting broadcast data and a broadcast clock signal can be shortened, and the risk of a mismatch between the broadcast data and the broadcast clock signal in a broadcast process can be reduced, thereby improving reliability of fuse array broadcast.

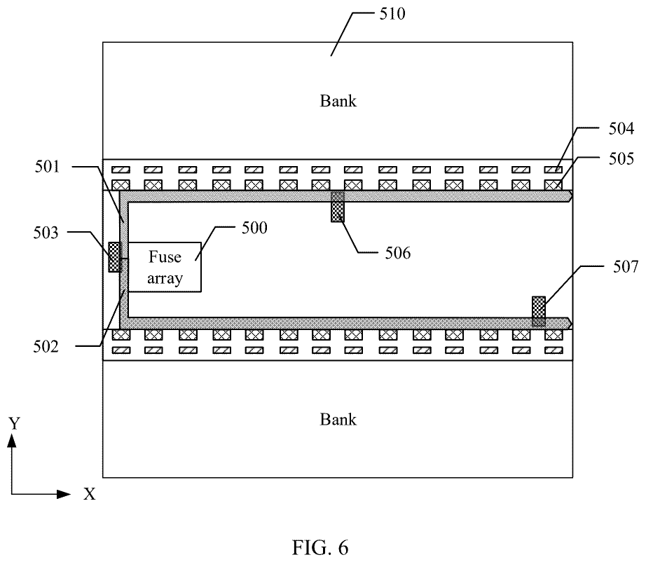

In some specific examples, FIG. 6 is a schematic arrangement diagram of a broadcast circuit for a fuse array according to an embodiment of the present disclosure. For ease of observation, a broadcast bus 501 in a first sub-broadcast circuit and a broadcast bus 502 in a second sub-broadcast circuit are shown in a perspective effect. As shown in FIG. 6, a fuse array 500 is located in a peripheral circuit between two banks 510, and a broadcast circuit for the fuse array includes two sub-broadcast circuits connected to the fuse array 500. The broadcast bus 501 in the first sub-broadcast circuit includes a part extending in an X direction and a part extending in a Y direction, and is connected to a test mode register 503 and multiple registers located on one side of the fuse array 500. The multiple registers may include local registers 504 of multiple column decoders, local registers 505 of multiple row decoders, and a test mode register 506. The broadcast bus 502 in the second sub-broadcast circuit also includes a part extending in the X direction and a part extending in the Y direction, and is connected to the test mode register 503 and multiple registers located on the other side of the fuse array 500. The multiple registers may include a test mode register 507. In this example, compared with a single broadcast bus that needs to be connected to all registers located on both sides of the fuse array 500, the broadcast bus 501 in the first sub-broadcast circuit and the broadcast bus 502 in the second sub-broadcast circuit have a smaller length. At the same moment, one of the broadcast bus 501 in the first sub-broadcast circuit and the broadcast bus 502 in the second sub-broadcast circuit is enabled, so that the winding length of a broadcast bus for transmitting broadcast data and a broadcast clock signal can be shortened, and the risk of a mismatch between the broadcast data and the broadcast clock signal in a broadcast process can be reduced, thereby improving reliability of fuse array broadcast.

It should be noted that, some registers in FIG. 5 and FIG. 6 are not directly connected to the broadcast bus, and branches configured to connect these registers to the broadcast bus are omitted in the figures. In addition, a broadcast address detector in the broadcast circuit, a gating circuit in the sub-broadcast circuit, and another structure are omitted in FIG. 5 and FIG. 6. For functions and circuit structures thereof, refer to descriptions of FIG. 1, FIG. 2, and FIG. 3 in the foregoing embodiments.

It should be noted that, in the foregoing embodiment, N being equal to 2 is taken as an example, but the present disclosure is not limited thereto. In some other embodiments, N may be any positive integer greater than 1, such as 3, 4, or 5. For example, when N is equal to 4, the broadcast circuit for the fuse array may include four sub-broadcast circuits, and each of the sub-broadcast circuits includes one gating circuit, one broadcast bus, and one latch circuit. The broadcast address detector may compare a quantity of broadcast fuses with four preset quantities in a preset list, and generate four enable signals. The four sub-broadcast circuits respectively receive the four enable signals, and a maximum of one of the four enable signals is valid. In other words, a maximum of one of four gating circuits may output gated broadcast data and a gated broadcast clock signal, so that data in the fuse array can be separately broadcast through the four sub-broadcast circuits. When a quantity of local registers remains unchanged, the length of each broadcast bus can be further shortened, and therefore the risk of a mismatch between broadcast data and a broadcast clock signal in a broadcast process can be further reduced, thereby improving reliability of fuse array broadcast.

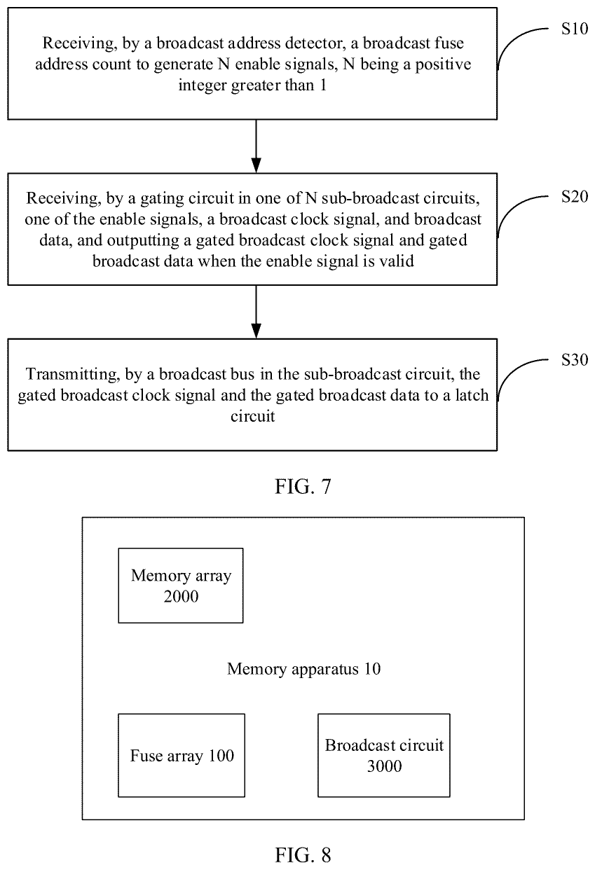

Based on a concept similar to that of the foregoing broadcast circuit for the fuse array, the present disclosure further provides a broadcast method for a fuse array. FIG. 7 is a schematic flowchart of a broadcast method for a fuse array according to an embodiment of the present disclosure. As shown in FIG. 7, the broadcast method for the fuse array includes the steps as follows.

In the step of S10, a broadcast address detector receives a broadcast fuse address count to generate N enable signals, where N is a positive integer greater than 1.

In the step of S20, a gating circuit in one of N sub-broadcast circuits receives one of the enable signals, a broadcast clock signal, and broadcast data, and outputs a gated broadcast clock signal and gated broadcast data when the enable signal is valid.

In the step of S30, a broadcast bus in the sub-broadcast circuit transmits the gated broadcast clock signal and the gated broadcast data to a latch circuit.

In some embodiments, with reference to FIG. 1 and FIG. 7, a specific process of step S10 includes the steps as follows: The broadcast address detector 101 receives the broadcast fuse address count to generate a quantity of broadcast fuses, and compares the quantity of broadcast fuses with a preset quantity in a preset list to generate the N enable signals, where the preset list includes N preset quantities, and a maximum of one of the N enable signals is valid. Herein, for example, N is equal to 2. The broadcast address detector 101 may generate an enable signal 1 and an enable signal 2.

In some embodiments, with reference to FIG. 2 and FIG. 7, that the first sub-broadcast circuit 200 broadcasts the fuse array is taken as an example. A specific process of step S20 includes the steps as follows: The clock gating circuit 2011 performs a logical operation on the enable signal 1 and the broadcast clock signal to generate the gated broadcast clock signal. The data gating circuit 2012 performs the logical operation on the enable signal 1 and the broadcast data to generate the gated broadcast data.

In some embodiments, with reference to FIG. 3 and FIG. 7, that the first sub-broadcast circuit 200 broadcasts the fuse array is taken as an example. A specific process of step S20 may include the steps as follows: The NAND gate 2013 of the clock gating circuit receives the enable signal 1 and the broadcast clock signal, and outputs an intermediate broadcast clock signal. The NOT gate 2014 of the clock gating circuit receives the intermediate broadcast clock signal, and outputs the gated broadcast clock signal. The NAND gate 2015 of the data gating circuit receives the enable signal 1 and the broadcast data, and outputs intermediate broadcast data. The NOT gate 2016 of the data gating circuit receives the intermediate broadcast data, and outputs the gated broadcast data.

In some embodiments, with reference to FIG. 4 and FIG. 7, that the first sub-broadcast circuit 200 broadcasts the fuse array is taken as an example. The broadcast method for the fuse array further includes the steps as follows: M flip-flops in the latch circuit 203 receive the gated broadcast clock signal and one enable signal, and output M selection control signals when the enable signal is valid, where a maximum of one of the M selection control signals is valid, and M is a positive integer greater than 1. The latches in the latch circuit 203 receive the selection control signals and the gated broadcast data, and latch and output the gated broadcast data when the selection control signals are valid.

In some specific examples, with reference to FIG. 1 and FIG. 7, before step S10, the broadcast circuit for the fuse array may be enabled in response to a fuse broadcast command. The broadcast method for the fuse array further includes the steps as follows: The broadcast clock signal generation circuit 103 generates a broadcast clock signal. The broadcast address counter circuit 102 receives the broadcast clock signal, and generates a broadcast fuse address count based on the broadcast clock signal.

In some specific examples, with reference to FIG. 1 and FIG. 7, a specific process of step S10 may include the steps as follows: The broadcast address detector 101 receives the broadcast fuse address count to generate a quantity of broadcast fuses, and compares the quantity of broadcast fuses with a preset quantity in a preset list to generate the enable signal 1 and the enable signal 2. Herein, the preset list may include two preset quantities. A first preset quantity may be a quantity X of fuses that may be broadcast by the first sub-broadcast circuit 200, and a second preset quantity may be the sum X+Y of the quantity of fuses that may be broadcast by the first sub-broadcast circuit 200 and a quantity of fuses that may be broadcast by the second sub-broadcast circuit 300.

In some specific examples, with reference to FIG. 1 and FIG. 7, the broadcast method for the fuse array may include the step as follows: When the quantity of broadcast fuses is less than X, the enable signal 1 is valid, the enable signal 2 is invalid, and the broadcast data may be broadcast through the first sub-broadcast circuit 200, which includes the steps as follows: In the step of S20, the gating circuit 201 in the first sub-broadcast circuit 200 receives the enable signal 1, a broadcast clock signal, and broadcast data, and outputs a first gated broadcast clock signal and first gated broadcast data. In the step of S30, the broadcast bus 202 in the first sub-broadcast circuit 200 transmits the first gated broadcast clock signal and the first gated broadcast data to the latch circuit 203. The latch circuit 203 receives the enable signal 1, the first gated broadcast clock signal, and the first gated broadcast data, and latches and outputs the first gated broadcast data.

In some specific examples, with reference to FIG. 1 and FIG. 7, the broadcast method for the fuse array may include the step as follows: When the quantity of broadcast fuses is greater than or equal to X and is less than X+Y, the enable signal 1 is invalid, the enable signal 2 is valid, and the broadcast data may be broadcast through the second sub-broadcast circuit 300, which includes the steps as follows: In the step of S20, the gating circuit 301 in the second sub-broadcast circuit 300 receives the enable signal 2, a broadcast clock signal, and broadcast data, and outputs a second gated broadcast clock signal and second gated broadcast data. In the step of S30, the broadcast bus 302 in the second sub-broadcast circuit 300 transmits the second gated broadcast clock signal and the second gated broadcast data to the latch circuit 303. The latch circuit 303 receives the enable signal 2, the second gated broadcast clock signal, and the second gated broadcast data, and latches and outputs the second gated broadcast data.

In some specific examples, the broadcast method for the fuse array may include the step as follows: When the quantity of broadcast fuses is equal to X+Y, both the enable signal 1 and the enable signal 2 are invalid, and broadcast of the fuse array is completed.

In this embodiment of the present disclosure, the broadcast address detector may generate N enable signals based on a broadcast progress, each of the N sub-broadcast circuits may receive one enable signal, the gating circuit in the sub-broadcast circuit may output gated broadcast data and a gated broadcast clock signal when the enable signal is valid, the broadcast bus in the sub-broadcast circuit may transmit the gated broadcast data and the gated broadcast clock signal to the latch circuit, and the latch circuit may latch and output the gated broadcast data when the enable signal is valid. A maximum of one of the N enable signals is valid, so that broadcast of the fuse array can be separately completed through the N sub-broadcast circuits. The length of broadcast buses in the N sub-broadcast circuits is less than the length of a single broadcast bus that needs to pass through all local registers. In other words, according to the broadcast method for the fuse array provided in the present disclosure, the risk of a mismatch between broadcast data and a broadcast clock signal in a process of broadcasting the fuse array can be reduced, and a probability of an error in broadcast data received by a local register is reduced, thereby improving reliability of fuse array broadcast.

FIG. 8 is a schematic diagram of composition of a memory apparatus according to an embodiment of the present disclosure. Referring to FIG. 8, an embodiment of the present disclosure further provides a memory apparatus 10, including a memory array 2000, a fuse array 100, and the broadcast circuit 3000 shown in the foregoing embodiment. The memory array 2000 is configured to store data, the fuse array 100 is configured to store repair information related to the memory array 2000, and the broadcast circuit 3000 is configured to broadcast the fuse array 100 after the memory apparatus 10 is powered on, to transmit, through the broadcast circuit 3000, the repair information stored in the fuse array 100 to local registers in the memory apparatus 10. The memory apparatus 10 may be a dynamic random access memory (DRAM), a ferroelectric random access memory (FRAM), a phase change memory (PCM), a magnetic random access memory (MRAM), a resistive random access memory (RRAM), or the like. A fuse unit in the fuse array 100 may be of a fuse structure, or may be of an anti-fuse structure.

The features disclosed in the several apparatus embodiments provided in the present disclosure may be randomly combined when there is no conflict, to obtain new apparatus embodiments.

The methods disclosed in the several method embodiments provided in the present disclosure may be randomly combined when there is no conflict, to obtain new method embodiments.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure.

What is claimed is:

1. A broadcast circuit for a fuse array, comprising:
a broadcast address detector, configured to receive a broadcast fuse address count to generate N enable signals, N being a positive integer greater than 1; and
N sub-broadcast circuits, each of the sub-broadcast circuits comprising:
a gating circuit, connected to the fuse array and the broadcast address detector, and configured to: receive one of the enable signals, a broadcast clock signal, and broadcast data, and output a gated broadcast clock signal and gated broadcast data when the enable signal is valid; and
a broadcast bus and a latch circuit, the broadcast bus being connected to the gating circuit and the latch circuit, and the broadcast bus being configured to transmit the gated broadcast clock signal and the gated broadcast data to the latch circuit.

2. The broadcast circuit for the fuse array according to claim 1, wherein the broadcast circuit for the fuse array further comprises:
a broadcast clock signal generation circuit, configured to generate the broadcast clock signal in response to a fuse broadcast command; and
a broadcast address counter circuit, configured to: receive the broadcast clock signal, and generate the broadcast fuse address count, the fuse array being configured to: receive the broadcast fuse address count, and output the broadcast data.

3. The broadcast circuit for the fuse array according to claim 1, wherein the broadcast address detector is specifically configured to:
receive the broadcast fuse address count to generate a quantity of broadcast fuses; and
compare the quantity of broadcast fuses with a preset quantity in a preset list to generate the N enable signals, the preset list comprising N preset quantities, and a maximum of one of the N enable signals being valid.

4. The broadcast circuit for the fuse array according to claim 1, wherein the gating circuit comprises:
a clock gating circuit, configured to perform a logical operation on the enable signal and the broadcast clock signal to generate the gated broadcast clock signal; and
a data gating circuit, configured to perform the logical operation on the enable signal and the broadcast data to generate the gated broadcast data.

5. The broadcast circuit for the fuse array according to claim 4, wherein the clock gating circuit and the data gating circuit each comprise a NAND gate and a NOT gate, and an output terminal of the NAND gate is connected to an input terminal of the NOT gate;
the NAND gate of the clock gating circuit is configured to: receive the enable signal and the broadcast clock signal, and output an intermediate broadcast clock signal;
the NOT gate of the clock gating circuit is configured to: receive the intermediate broadcast clock signal, and output the gated broadcast clock signal;
the NAND gate of the data gating circuit is configured to: receive the enable signal and the broadcast data, and output intermediate broadcast data; and
the NOT gate of the data gating circuit is configured to: receive the intermediate broadcast data, and output the gated broadcast data.

6. The broadcast circuit for the fuse array according to claim 1, wherein the latch circuit comprises M flip-flops and M latches, a control terminal of each of the latches is connected to an output terminal of one of the flip-flops, and M is a positive integer greater than 1;
the M flip-flops are configured to: receive the gated broadcast clock signal and one of the enable signals, and output M selection control signals when the enable signal is valid, a maximum of one of the M selection control signals being valid; and
the latches are configured to: receive the selection control signals and the gated broadcast data, and latch and output the gated broadcast data when the selection control signals are valid.

7. The broadcast circuit for the fuse array according to claim 6, wherein the M flip-flops are connected in series, and a first flip-flop in the M flip-flops comprises:
a first data input terminal, configured to receive a ground voltage;
a first clock input terminal, configured to receive the gated broadcast clock signal; and
a setting terminal, configured to receive the enable signal;
a flip-flop other than the first flip-flop in the M flip-flops comprises:
a second data input terminal, connected to an output terminal of a previous flip-flop;
a second clock input terminal, configured to receive the gated broadcast clock signal; and
a reset terminal, configured to receive the enable signal.

8. The broadcast circuit for the fuse array according to claim 1, wherein the broadcast bus comprises a data bus and a clock bus, the data bus is configured to transmit the gated broadcast data to the latch circuit, and the clock bus is configured to transmit the gated broadcast clock signal to the latch circuit.

9. A broadcast method for a fuse array, comprising:
S10: receiving, by a broadcast address detector, a broadcast fuse address count to generate N enable signals, N being a positive integer greater than 1;
S20: receiving, by a gating circuit in one of N sub-broadcast circuits, one of the enable signals, a broadcast clock signal, and broadcast data, and outputting a gated broadcast clock signal and gated broadcast data when the enable signal is valid; and
S30: transmitting, by a broadcast bus in the sub-broadcast circuit, the gated broadcast clock signal and the gated broadcast data to a latch circuit.

10. The broadcast method for the fuse array according to claim 9, wherein the receiving, by a broadcast address detector, a broadcast fuse address count to generate N enable signals comprises:
receiving, by the broadcast address detector, the broadcast fuse address count to generate a quantity of broadcast fuses; and
comparing the quantity of broadcast fuses with a preset quantity in a preset list to generate the N enable signals, the preset list comprising N preset quantities, and a maximum of one of the N enable signals being valid.

11. The broadcast method for the fuse array according to claim 9, wherein the receiving, by a gating circuit in one of N sub-broadcast circuits, one of the enable signals, a broadcast clock signal, and broadcast data, and outputting a gated broadcast clock signal and gated broadcast data when the enable signal is valid comprises:
performing, by a clock gating circuit, a logical operation on the enable signal and the broadcast clock signal to generate the gated broadcast clock signal; and
performing, by a data gating circuit, the logical operation on the enable signal and the broadcast data to generate the gated broadcast data.

12. The broadcast method for the fuse array according to claim 11, wherein the performing, by a clock gating circuit, a logical operation on the enable signal and the broadcast clock signal to generate the gated broadcast clock signal comprises:
receiving, by a NAND gate of the clock gating circuit, the enable signal and the broadcast clock signal, and outputting an intermediate broadcast clock signal; and
receiving, by a NOT gate of the clock gating circuit, the intermediate broadcast clock signal, and outputting the gated broadcast clock signal; and
the performing, by a data gating circuit, the logical operation on the enable signal and the broadcast data to generate the gated broadcast data comprises:
receiving, by a NAND gate of the data gating circuit, the enable signal and the broadcast data, and outputting intermediate broadcast data; and
receiving, by a NOT gate of the data gating circuit, the intermediate broadcast data, and outputting the gated broadcast data.

13. The broadcast method for the fuse array according to claim 9, wherein the broadcast method for the fuse array further comprises:
receiving, by M flip-flops in the latch circuit, the gated broadcast clock signal and one of the enable signals, and outputting M selection control signals when the enable signal is valid, a maximum of one of the M selection control signals being valid, and M being a positive integer greater than 1; and
receiving, by latches in the latch circuit, the selection control signals and the gated broadcast data, and latching and outputting the gated broadcast data when the selection control signals are valid.

14. A memory apparatus, comprising a memory array, a fuse array, and the broadcast circuit according to claim 1, the memory array being configured to store data, the fuse array being configured to store repair information related to the memory array, and the broadcast circuit being configured to broadcast the fuse array after the memory apparatus is powered on, to transmit, through the broadcast circuit, the repair information stored in the fuse array to local registers in the memory apparatus.
